(19) United States
(12) Patent Application Publication
(10) Pub. No.: US 2026/0171755 A1
(43) Pub. Date: Jun. 18, 2026

(54) VERTICAL-CAVITY SURFACE-EMITTING SEMICONDUCTOR LASER AND METHOD FOR MANUFACTURING VERTICAL-CAVITY SURFACE-EMITTING SEMICONDUCTOR LASER

(71) Applicant: SONY GROUP CORPORATION, TOKYO (JP)

(72) Inventors: HIROSHI NAKAJIMA, TOKYO (JP); MIKIHIRO YOKOZEKI, TOKYO (JP); TOMOMASA WATANABE, TOKYO (JP); DAIJI KASAHARA, TOKYO (JP)

(21) Appl. No.: 18/574,932

(22) PCT Filed: Feb. 7, 2022
(86) PCT No.: PCT/JP2022/004594

§ 371 Date: Dec. 28, 2023

(30) Foreign Application Priority Data
Jul. 9, 2021 (JP) 2021-114409

(51) Int. Cl. H01S 5/183; H01S 5/32; H01S 5/343

(52) U.S. Cl. CPC H01S 5/18308; H01S 5/3202; H01S 5/34313

(57) ABSTRACT

Providing a vertical-cavity surface-emitting semiconductor laser and a method for manufacturing a surface-emitting laser that are capable of preventing warpage of a substrate, particularly a GaAs substrate, and also increasing in-plane uniformity to enhance yield and device characteristics. The present technology is to provide a vertical-cavity surface-emitting semiconductor laser that includes: a substrate; a first semiconductor stacked structure formed with at least a first DBR layer; a second semiconductor stacked structure formed with at least a first conductivity-type semiconductor layer, a second conductivity-type semiconductor layer, and a semiconductor active layer disposed between the first conductivity-type semiconductor layer and the second conductivity-type semiconductor layer; and a second DBR layer, in this order. In the vertical-cavity surface-emitting semiconductor laser, the first semiconductor stacked structure includes at least a 1-1st semiconductor layer having a lattice constant greater than the lattice constant of the GaAs substrate, and a 1-2nd semiconductor layer having a lattice constant smaller than the lattice constant of the GaAs substrate, and the second semiconductor stacked structure contains at least InP.

### TECHNICAL FIELD

The present technology relates to a vertical-cavity surface-emitting semiconductor laser and a method for manufacturing the vertical-cavity surface-emitting semiconductor laser.

### BACKGROUND ART

A vertical-cavity surface-emitting semiconductor laser (a surface-emitting laser) has various advantages, compared with an edge-emitting semiconductor laser (an edge-emitting laser). For this reason, research and development of vertical-cavity surface-emitting semiconductor lasers (surface-emitting lasers) are being actively conducted these days (see Patent Document 1, for example).

### CITATION LIST

### Patent Document

Patent Document 1: Japanese Patent Application Laid-Open No. 11-186653

### SUMMARY OF THE INVENTION

### Problems to be Solved by the Invention

However, in a vertical-cavity surface-emitting semiconductor laser formed by bonding substrates, particularly a GaAs substrate and a substrate, to each other, or particularly in an InP-based surface-emitting semiconductor laser, the technique suggested in Patent Document 1 might not be able to prevent warpage of a substrate, particularly a GaAs substrate, and furthermore, might not be able to increase in-plane uniformity to enhance yield and device characteristics.

Therefore, the present technology has been made in view of such circumstances, and a principal objective of the present technology is to provide a vertical-cavity surface-emitting semiconductor laser and a method for manufacturing a surface-emitting laser that are capable of preventing warpage of a substrate, particularly a GaAs substrate, and also increasing in-plane uniformity to enhance yield and device characteristics.

### Solutions to Problems

As a result of intensive studies conducted to achieve the above object, the present inventors have surprisingly succeeded in preventing warpage of a substrate, particularly a GaAs substrate, and enhancing yield and device characteristics by increasing in-plane uniformity, and thus have completed the present technology.

Specifically, the present technology provides, as a first aspect, a vertical-cavity surface-emitting semiconductor laser that includes:
a substrate;
a first semiconductor stacked structure including at least a first DBR layer;
a second semiconductor stacked structure in which at least a first conductivity-type semiconductor layer, a semiconductor active layer, and a second conductivity-type semiconductor layer are formed in this order from the side of the substrate; and
a second DBR layer, in this order,
in which
the first semiconductor stacked structure includes at least a 1-1st semiconductor layer having a lattice constant greater than the lattice constant of the substrate, and a 1-2nd semiconductor layer having a lattice constant smaller than the lattice constant of the substrate, and
the second semiconductor stacked structure contains at least InP.

In the vertical-cavity surface-emitting semiconductor laser according to the first aspect of the present technology,
the substrate may be a GaAs substrate.

In the vertical-cavity surface-emitting semiconductor laser according to the first aspect of the present technology,
the first DBR layer may include the 1-1st semiconductor layer, and
the 1-1st semiconductor layer may contain AlₓGa₁₋ₓAs (0<x≤1).

In the vertical-cavity surface-emitting semiconductor laser according to the first aspect of the present technology,
the 1-2nd semiconductor layer may include a mixed crystal semiconductor containing at least Ga and P.

In the vertical-cavity surface-emitting semiconductor laser according to the first aspect of the present technology,
the 1-2nd semiconductor layer may contain GaAsₓP₁₋ₓ(0≤x<1) or GaₓIn₁₋ₓP (0≤x<1).

In the vertical-cavity surface-emitting semiconductor laser according to the first aspect of the present technology,
the first DBR layer may include the semiconductor layer 1-2.

In the vertical-cavity surface-emitting semiconductor laser according to the first aspect of the present technology,
the thickness of the 1-2nd semiconductor layer may be equal to or smaller than 5 μm, and
the rate of lattice mismatch of the 1-2nd semiconductor layer with the substrate may be equal to or lower than 1%.

In the vertical-cavity surface-emitting semiconductor laser according to the first aspect of the present technology,
the semiconductor active layer may include a quantum well structure formed with AlGaInAs or GaInAsP, and
the oscillation wavelength may be not smaller than 1.2 μm and not greater than 2 μm.

In the vertical-cavity surface-emitting semiconductor laser according to the first aspect of the present technology,
the second DBR layer may include a dielectric material, and
the dielectric material may contain at least one compound selected from the group consisting of SiO₂, TiO₂, Ta₂O₅, SiN, amorphous Si, MgF₂, and CaF₂.

Also, the present technology provides, as a second aspect, a method for manufacturing a vertical-cavity surface-emitting semiconductor laser, including at least:
growing a first semiconductor stacked structure on a substrate, the first semiconductor stacked structure including at least a first DBR layer;
bonding an InP substrate directly onto the first semiconductor stacked structure;
cutting off a portion of the InP substrate;
growing a second semiconductor stacked structure on the uncut InP substrate, the second semiconductor stacked structure including at least a first conductivity-type semiconductor layer, a semiconductor active layer, and a second conductivity-type semiconductor layer that are formed in this order from the side of the substrate; and
forming a second DBR layer on the second semiconductor stacked structure.

In the method according to the second aspect of the present technology,
the substrate may be a GaAs substrate.

In the method according to the second aspect of the present technology,
the first semiconductor stacked structure may include at least a 1-1st semiconductor layer having a lattice constant greater than the lattice constant of the substrate, and a 1-2nd semiconductor layer having a lattice constant smaller than the lattice constant of the substrate.

In the method according to the second aspect of the present technology,
the first DBR layer may include the 1-1st semiconductor layer, and
the 1-1st semiconductor layer may contain AlₓGa₁₋ₓAs (0<x≤1).

In the method according to the second aspect of the present technology,
the 1-2nd semiconductor layer may include a mixed crystal semiconductor containing at least Ga and P.

In the method according to the second aspect of the present technology,
the 1-2nd semiconductor layer may contain GaASₓP₁₋ₓ (0≤x <1) or GaₓIn₁₋ₓP (0≤x<1).

In the method according to the second aspect of the present technology,
the first DBR layer may include the 1-2nd semiconductor layer.

In the method according to the second aspect of the present technology,
the thickness of the 1-2nd semiconductor layer may be equal to or smaller than 5 μm, and
the rate of lattice mismatch of the 1-2nd semiconductor layer with the substrate may be equal to or lower than 1%.

In the method according to the second aspect of the present technology,
the semiconductor active layer may include a quantum well structure formed with AlGaInAs or GaInAsP, and
the oscillation wavelength may be not smaller than 1.2 μm and not greater than 2 μm.

In the method according to the second aspect of the present technology,
the second DBR layer may include a dielectric material, and
the dielectric material may contain at least one compound selected from the group consisting of SiO₂, TiO₂, Ta₂O₅, SiN, amorphous Si, MgF₂, and CaF₂.

According to the present technology, warpage of a substrate, particularly a GaAs substrate, is prevented, and in-plane uniformity is increased, to enhance yield and device characteristics. Note that the effects described herein are not necessarily restrictive, and any of the effects described in the present disclosure may be exhibited.

### BRIEF DESCRIPTION OF DRAWINGS

FIG. 1 is a diagram illustrating an example configuration of a vertical-cavity surface-emitting semiconductor laser according to a first embodiment to which the present technology is applied.

FIG. 2 is a diagram illustrating an example configuration of a vertical-cavity surface-emitting semiconductor laser according to a second embodiment to which the present technology is applied.

FIG. 3 is a diagram illustrating an example configuration of a vertical-cavity surface-emitting semiconductor laser according to a third embodiment to which the present technology is applied.

FIG. 4 is a diagram illustrating an example configuration of a vertical-cavity surface-emitting semiconductor laser according to a fourth embodiment to which the present technology is applied.

FIG. 5 is a diagram illustrating an example configuration of a vertical-cavity surface-emitting semiconductor laser according to a fifth embodiment to which the present technology is applied.

FIG. 6 is a diagram illustrating an example configuration of a vertical-cavity surface-emitting semiconductor laser according to a sixth embodiment to which the present technology is applied.

FIG. 7 is diagrams for explaining a method for manufacturing the vertical-cavity surface-emitting semiconductor laser according to the first embodiment to which the present technology is applied.

FIG. 8 is diagrams for explaining the method for manufacturing the vertical-cavity surface-emitting semiconductor laser according to the first embodiment to which the present technology is applied.

FIG. 9 is diagrams for explaining the method for manufacturing the vertical-cavity surface-emitting semiconductor laser according to the first embodiment to which the present technology is applied.

FIG. 10 is diagrams for explaining the method for manufacturing the vertical-cavity surface-emitting semiconductor laser according to the first embodiment to which the present technology is applied.

### MODE FOR CARRYING OUT THE INVENTION

The following is a description of preferred modes for carrying out the present technology. Each embodiment described below represents an example of a typical embodiment of the present technology, and the scope of the present technology is not narrowed by this. Note that, in the drawings, “upper” means an upward direction or an upper side in the drawings, “lower” means a downward direction or a lower side in the drawings, “left” means a leftward direction or a left side in the drawings, and “right” means a rightward direction or a right side in the drawings, unless otherwise specified.

Further, in the description using the drawings, the same or equivalent elements or members are denoted by the same reference signs, and repetitive explanation will not be made unless there is a specific reason.

Note that explanation will be made in the following order.
1. Overview of the present technology
2. First embodiment (Example 1 of a vertical-cavity surface-emitting semiconductor laser, and Example 1 of a method for manufacturing the vertical-cavity surface-emitting semiconductor laser)
3. Second embodiment (Example 2 of a vertical-cavity surface-emitting semiconductor laser)
4. Third embodiment (Example 3 of a vertical-cavity surface-emitting semiconductor laser)
5. Fourth embodiment (Example 4 of a vertical-cavity surface-emitting semiconductor laser)
6. Fifth embodiment (Example 5 of a vertical-cavity surface-emitting semiconductor laser)
7. Sixth embodiment (Example 6 of a vertical-cavity surface-emitting semiconductor laser)

### 1. Overview of the Present Technology

First, an overview of the present technology is described. The present technology is a technology relating to a vertical-cavity surface-emitting semiconductor laser and a method for manufacturing the vertical-cavity surface-emitting semiconductor laser.

Infrared surface-emitting lasers (vertical-cavity surface-emitting lasers; VCSELs) in the 940 nm band are being used these days as three-dimensional sensing light sources for face authentication by smartphones or the like. To increase authentication accuracy, it is effective to increase the light output of the light source. However, there is a limitation on the light output that cannot be increased to a predetermined value or greater, because of danger to the human eye. This upper limit of the light output is called a damage threshold, and increases as the wavelength of the laser becomes longer, and particularly, increases greatly in a band of 1.4 μm and longer. Therefore, the wavelength band of 1.4 μm and longer are called the eye-safe band.

In view of this, a laser light source having a wavelength of 1.4 μm or longer is expected as a next-generation sensing light source. Further, as for the structure of a laser to be used for sensing, a VCSEL that is less expensive and easier to array than a conventional edge-emitting laser is preferable.

An InP substrate is suitable as a substrate on which the crystal of a semiconductor laser that oscillates at a wavelength of 1.4 μm or longer is formed. In an InP substrate, however, there is no semiconductor DBR that is lattice-matched to the substrate, has a wide stopband width, and has a high heat conductivity, like AlAs/GaAs of a GaAs substrate. Examples of semiconductor DBRs lattice-matched to an InP substrate include AlGaInAs/InP and AlGaInAs/AlInAs. However, both AlGaInAs/InP and AlGaInAs/AlInAs have a small refractive index difference, a small stopband width, a low heat release efficiency, and a low heat conductivity as a mixed crystal material. Therefore, such a semiconductor DBR may be inferior to an AlAs/GaAs semiconductor DBR.

By an example technology, an AlAs/GaAs DBR film is formed on a GaAs substrate, and the GaAs substrate is bonded to an InP substrate on which an active layer has been grown. As a result, the stopband width of the DBR is increased, and an InP-based VCSEL having excellent heat release properties can be formed. By this method, however, when the GaAs substrate is bonded to the InP substrate, strain due to the AlAs in the AlAs/GaAs DBR causes warpage in the GaAs substrate, and therefore, the yield might decrease. The rate of lattice mismatch of AlAs with GaAs is +0.12%, which is very low, and therefore, does not greatly affect a conventional GaAs-based VCSEL. However, when a GaAs substrate is bonded to an InP substrate and is used as a DBR of an InP-based long-wavelength band VCSEL, the influence cannot be ignored. Furthermore, since the diameters of substrates are being made larger these days for the purpose of cost reduction, the influence of strain is considered to be a more serious technical problem in the future.

The present technology has been made in view of the above circumstances. According to the present technology, warpage of a GaAs substrate having a semiconductor DBR film formed thereon is prevented before substrate bonding, so that the characteristics and the yield of an InP-based VCSEL can be enhanced.

By the present technology, AlAs/GaAsP is adopted in place of AlAs/GaAs, so that strain of AlAs can be compensated for, and warpage of the GaAs substrate can be prevented. As a result, the yield by bonding increases, the stopband becomes wider, the heat conductivity also becomes higher, and thus, the characteristics of the device can be enhanced.

The composition of GaAsP is preferably GaAs_{0.97}P_{0.03} (da/a=−0.12%) having the same amount of strain as AlAs. Note that da/a at this point of time represents the lattice mismatch rate, which is (the lattice constant of GaAS_{0.97}P_{0.03}—the lattice constant of GaAs)/(the lattice constant of GaAs). The GaAsP layer may be disposed on the entire layer of the DBR, or may be disposed on part of the layer. Alternatively, the GaAsP layer may be inserted as one layer on the lower side (the substrate side) of the DBR layer. When the GaAsP layer is provided as one layer, and the composition of GaASP is GaAs_{0.9}P_{0.1}, for example, da/a=(the lattice constant of GaAs_{0.9}P_{0.1}—the lattice constant of GaAs)/(the lattice constant of GaAs)=−0.36%, and the thickness of the GaAs_{0.9}P_{0.1}layer may be 500 nm. Meanwhile, the lattice constants of GaP, GaAs, and AlAs are 5.451 Å, 5.654 Å, and 5.661 Å, respectively.

The above description is an overview of the present technology. In the description below, preferred modes for carrying out the present technology are specifically explained in detail, with reference to the drawings.

Each embodiment described below represents an example of a typical embodiment of the present technology, and the scope of the present technology is not narrowed by this.

### 2. First Embodiment (Example 1 of a Vertical-Cavity Surface-Emitting Semiconductor Laser, and Example 1 of a Method for Manufacturing the Vertical-Cavity Surface-Emitting Semiconductor Laser)

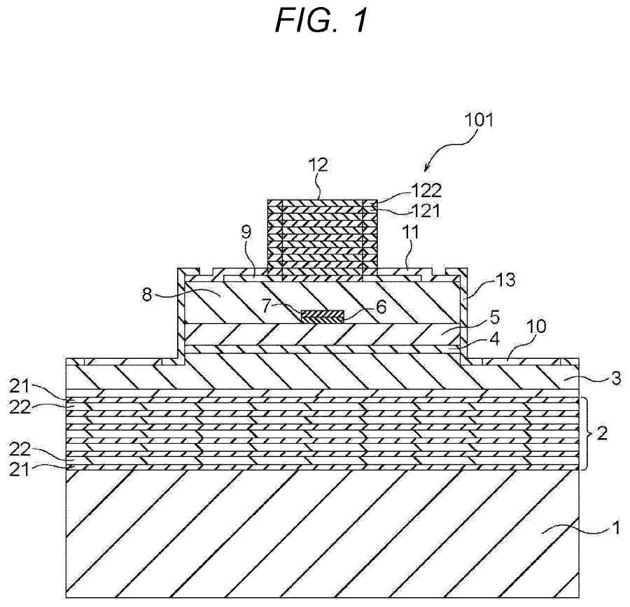

A vertical-cavity surface-emitting semiconductor laser according to a first embodiment (Example 1 of a vertical-cavity surface-emitting semiconductor laser) of the present technology is described with reference to FIG. 1.

FIG. 1 is a diagram illustrating an example configuration of a vertical-cavity surface-emitting semiconductor laser according to the first embodiment of the present technology, and specifically, is a cross-sectional diagram illustrating a vertical-cavity surface-emitting semiconductor laser 101.

The vertical-cavity surface-emitting semiconductor laser 101 includes a GaAs substrate 1, a first semiconductor stacked structure, a second semiconductor stacked structure, and a second DBR layer 12 in this order. The first semiconductor stacked structure is formed with a first DBR layer 2. The second semiconductor stacked structure includes a first conductivity-type semiconductor layer formed with an n-InP layer 3, a semiconductor active layer 4, and a second conductivity-type semiconductor layer formed with a p-InP layer 5, in this order from the side of the GaAs substrate 1.

The first DBR layer 2 forming the first semiconductor stacked structure includes 1-1st semiconductor layers 21 having a lattice constant greater than the lattice constant of the GaAs substrate 1, and 1-2nd semiconductor layers 22 having a lattice constant smaller than the lattice constant of the GaAs substrate 1. The 1-1st semiconductor layers 21 are formed with AlAs, and the 1-2nd semiconductor layers 22 are formed with GaAs_{0.97}P_{0.03}. Further, as described above, the second semiconductor stacked structure contains InP.

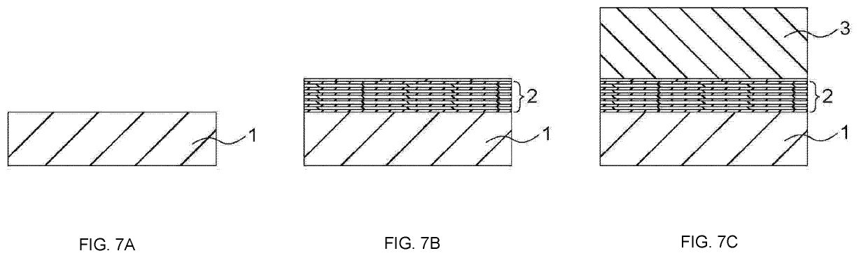

A method for manufacturing a vertical-cavity surface-emitting semiconductor laser according to the first embodiment (Example 1 of a method for manufacturing a vertical-cavity surface-emitting semiconductor laser) of the present technology is now described with reference to FIGS. 7 to 10.

FIGS. 7 to 10 are diagrams for explaining a method for manufacturing the vertical-cavity surface-emitting semiconductor laser (the vertical-cavity surface-emitting semiconductor laser 101) according to the first embodiment of the present technology.

The first DBR layer 2 (1-1st semiconductor layers (n-AlAs layers)/1-2nd semiconductor layers (n-GaAs_{0.097}P_{0.03} layers)) is grown on the n-type GaAs substrate 1 by MOCVD. The thickness of each layer in the first DBR layer (n-DBR layer) 2 is λ/4 in optical thickness, and the number of pairs (stacked structures of a 1-1st semiconductor layer 21 and a 1-2nd semiconductor layer 22) is 30, for example. The outermost surface is preferably a 1-2nd semiconductor layer (an n-GaAs_{0.097}P_{0.03}layer), or GaAs having an optical thickness of λ/4 instead.

Both layers are preferably undoped, but may be of the n-type with a doping concentration of about 5×10¹⁷ to 1×10¹⁸ [cm⁻³]. The dopant is Si, for example. An n-InP substrate 3 is bonded to the surface of the GaAs substrate 1 on the side of the first DBR layer 2 (the surface of the first DBR layer 2 on the opposite side from the side of the GaAs substrate 1). At this point of time, protons are implanted into the n-InP substrate 3 at a position of 100 nm from the surface, and the surface on the side into which the protons have been implanted is bonded to the GaAs substrate 1. As illustrated in FIG. 7C, the bonding is preferably direct bonding without interposition of metal or the like in between.

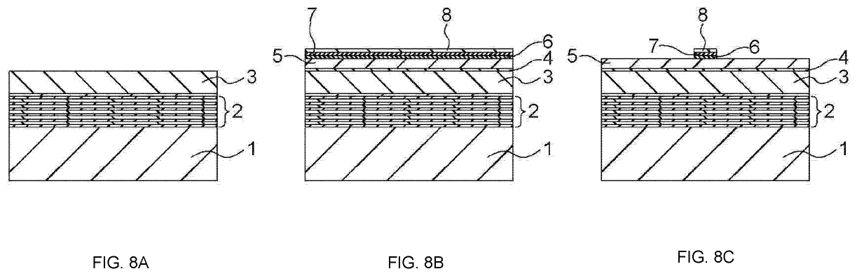

Next, the bonded n-InP substrate 3 is cut along the proton-implanted layer by heat treatment. As a result, the n-InP substrate 3 of 100 nm in thickness remains as a thin film on the side of the GaAs substrate 1 (FIG. 8A). Next, the substrate (a semi-finished product) is placed in an MOCVD device, and the n-InP layer 3, an AlGaInAs/AlGaInAs multiple quantum well layer (the semiconductor active layer) 4, the p-InP layer 5, a tunnel junction layer of a p⁺-AlGaInAs layer 6/an n⁺-AlGaInAs layer 7, and an n-InP layer 8 are sequentially grown on the thin n-InP substrate 3 (FIG. 8B).

Si can be used as an n-type dopant, and Mg can be used as a p-type dopant. The dopant in the p⁺-AlGaInAs layer 6 of the tunnel junction is preferably C, which is hardly diffused. Each doping concentration in the tunnel junction layer of the p⁺-AlGaInAs layer 6/the n⁺-AlGaInAs layer 7 may be 5×10¹⁹ [cm⁻³], and the doping concentrations in the other layers may be about 5×10¹⁷ to 1×10¹⁸ [cm⁻³].

In the AlGaInAs/AlGaInAs multiple quantum well layer (the semiconductor active layer) 4, the composition and the thickness may be designed so that the emission wavelength becomes 1450 nm, but it is preferable to apply opposite strains to the well layer and the barrier layer. The magnitude of the lattice mismatch rate may be about 0.5%, and the number of wells may be four. The thicknesses of the p⁺-AlGaInAs layer 6/the n⁺-AlGaInAs layer 7 in the tunnel junction layer may be 20 nm/20 nm, and the tunnel junction layer of the p⁺-AlGaInAs layer 6/the n⁺-AlGaInAs layer 7 is preferably disposed at a position separated from the AlGaInAs/AlGaInAs multiple quantum well layer (the semiconductor active layer) 4 by an optical distance of λ/4.

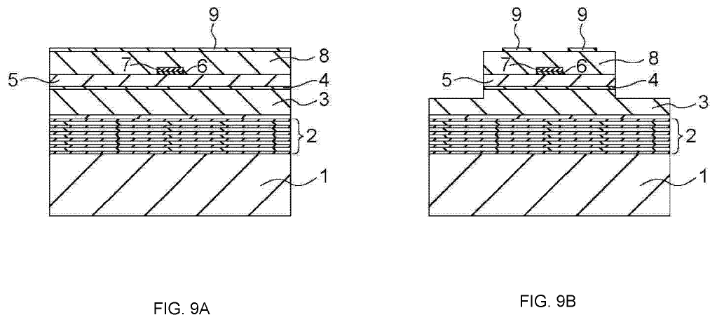

Next, the substrate (a semi-finished product) is taken out from the MOCVD device, and a mesa of the p⁺-AlGaInAs layer 6/the n⁺-AlGaInAs layer 7/the n-InP layer 8 is formed by a lithography process (FIG. 8C). The diameter (o) of the mesa is, for example, 8 μm to 10 μm. Etching is performed by wet etching, the n-InP layer 8 as the uppermost layer is subjected to etching with a mixed solution containing hydrogen bromide and hydrogen peroxide, and the p⁺-AlGaInAs layer 6/the n⁺-AlGaInAs layer 7 is subjected to etching with a mixed aqueous solution containing sulfuric acid and hydrogen peroxide. The wafer (a semi-finished product) on which the mesa is formed is again placed in the MOCVD device, and the n-InP layer 8 and an n-InGaAs layer 9 are grown (FIG. 9A). The doping concentration in the n-InP layer 8 is 5×10¹⁷ to 1×10¹⁸ [cm⁻³], and the doping concentration in the n-InGaAs layer 9 is 2×10¹⁹[cm⁻³].

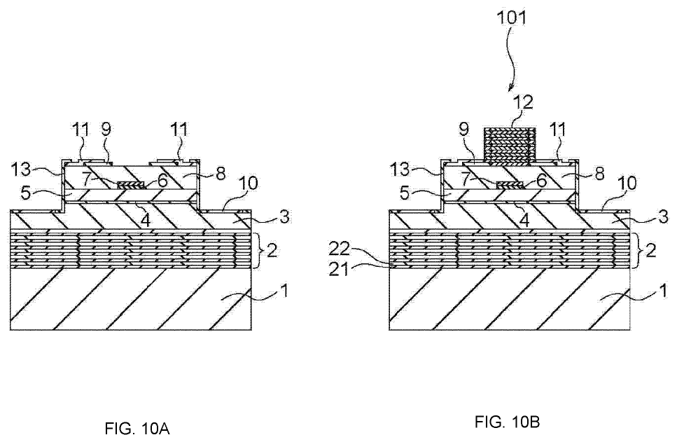

Next, the n-InGaAs layer 9 as the uppermost layer is removed by selective etching to remain in a donut-like shape having an inner diameter of 10 μm and an outer diameter of 50 μm (FIG. 9B), and a ring-like upper electrode 11 is then formed over the remaining n-InGaAs layer 9 (FIG. 10A). A mesa is formed so as to match the outer diameter of the upper electrode 11 (the diameter (φ) of the mesa is, for example, 50 μm) by a lithography process (FIGS. 9B and 10A). At this point of time, a lower portion of the mesa is the n-InP layer 8, and the mesa is preferably formed by dry etching. After a lower electrode 10 is formed on the n-InP layer 3, the mesa side surfaces are insulated with a SiN layer 13 or the like. After that, a multilayer film of Si02 layers 121/Ta₂O₅ layers 122 is formed as the second DBR layer 12. Note that, as one layer (film) of the multilayer film, any dielectric material may be used, and, for example, TiO₂ may be used. The thickness of each layer is λ/4 in optical thickness, and the number of pairs (stacked structures of a SiO₂ layer 121 and a Ta₂O₅ layer 122) is eight, for example. The portion of the multilayer film formed with the Si 02 layers 121/the Ta₂O₅ layers 122 formed outside the opening portion is selectively removed by a lithography process (FIG. 10B). Lastly, the device is singulated and mounted on a heat sink, and the electrodes are wire-bonded (not illustrated). In the above manner, the vertical-cavity surface-emitting semiconductor laser 101 is manufactured.

The contents described above regarding the vertical-cavity surface-emitting semiconductor laser and the method for manufacturing the vertical-cavity surface-emitting semiconductor laser according to the first embodiment (Example 1 of a vertical-cavity surface-emitting semiconductor laser and Example 1 of a method for manufacturing a vertical-cavity surface-emitting semiconductor laser) of the present technology can be applied to vertical-cavity surface-emitting semiconductor lasers according to the later-described second to sixth embodiments of the present technology, unless there is a specific technical contradiction.

### 3. Second Embodiment (Example 2 of a Vertical-Cavity Surface-Emitting Semiconductor Laser)

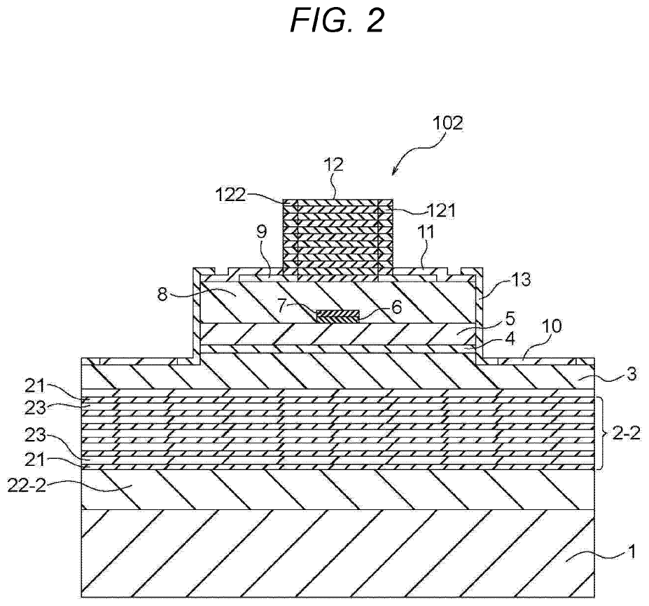

A vertical-cavity surface-emitting semiconductor laser according to a second embodiment (Example 2 of a vertical-cavity surface-emitting semiconductor laser) of the present technology is described with reference to FIG. 2.

FIG. 2 is a diagram illustrating an example configuration of a vertical-cavity surface-emitting semiconductor laser according to the second embodiment of the present technology, and specifically, is a cross-sectional diagram illustrating a vertical-cavity surface-emitting semiconductor laser 102.

The vertical-cavity surface-emitting semiconductor laser 102 includes a GaAs substrate 1, a first semiconductor stacked structure, a second semiconductor stacked structure, and a second DBR layer 12 in this order. The first semiconductor stacked structure is formed with a 1-2nd semiconductor layer 22-2 and a first DBR layer 2-2 in this order from the side of the GaAs substrate 1. The thickness of the 1-2nd semiconductor layer 22-2 is 5 μm or smaller, and the strain is 1% or less. The first DBR layer 2-2 is formed with 1-1st semiconductor layers 21 and n-GaAs layers 23. The second semiconductor stacked structure includes a first conductivity-type semiconductor layer formed with an n-InP layer 3, a semiconductor active layer 4, and a second conductivity-type semiconductor layer formed with a p-InP layer 5, in this order from the side of the GaAs substrate 1.

The first semiconductor stacked structure includes 1-1st semiconductor layers 21 having a lattice constant greater than the lattice constant of the GaAs substrate 1, and 1-2nd semiconductor layers 22 having a lattice constant smaller than the lattice constant of the GaAs substrate 1. The 1-1st semiconductor layers 21 are formed with AlAs, and the 1-2nd semiconductor layer 22-2 is formed with GaAs_{0.9}P_{0.1}. The thickness of the 1-2nd semiconductor layer 22-2 is 5 μm or smaller (500 nm in FIG. 2), and the rate of lattice mismatch with the GaAs substrate 1 is 1% or lower. Further, as described above, the second semiconductor stacked structure contains InP.

In the method for manufacturing the vertical-cavity surface-emitting semiconductor laser 102, the 1-2nd semiconductor layer 22-2 (an n-GaAs_{0.9}P_{0.1} layer (500 nm in thickness)) and the first DBR layer 2-2 (an n-DBR layer (the 1-1st semiconductor layers 21 (n-AlAs layers)/the n-GaAs layers 23) are grown on the n-type GaAs substrate 1 by MOCVD. The uppermost layer is preferably an n-GaAs layer 23. Further, other than the above aspects, in the method for manufacturing the vertical-cavity surface-emitting semiconductor laser 102, the above-described method for manufacturing the vertical-cavity surface-emitting semiconductor laser according to the first embodiment (Example 1 of a method for manufacturing a vertical-cavity surface-emitting semiconductor laser) of the present technology can be applied.

The contents described above regarding the vertical-cavity surface-emitting semiconductor laser according to the second embodiment (Example 2 of a vertical-cavity surface-emitting semiconductor laser) of the present technology can be applied to the vertical-cavity surface-emitting semiconductor laser and the method for manufacturing the vertical-cavity surface-emitting semiconductor laser according to the above-described first embodiment of the present technology, and the vertical-cavity surface-emitting semiconductor lasers according to the later-described third to sixth embodiments of the present technology, unless there is a specific technical contradiction.

### 4. Third Embodiment (Example 3 of a Vertical-Cavity Surface-Emitting Semiconductor Laser)2

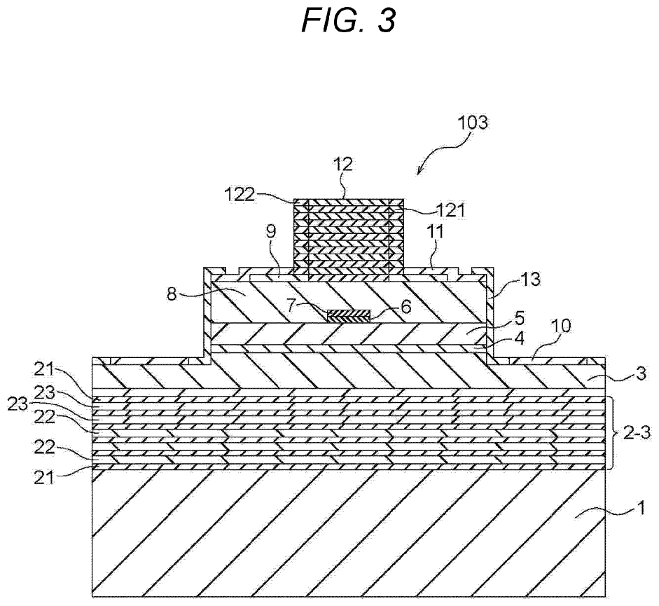

A vertical-cavity surface-emitting semiconductor laser according to a third embodiment (Example 3 of a vertical-cavity surface-emitting semiconductor laser) of the present technology is described with reference to FIG. 3.

FIG. 3 is a diagram illustrating an example configuration of a vertical-cavity surface-emitting semiconductor laser according to the third embodiment of the present technology, and specifically, is a cross-sectional diagram illustrating a vertical-cavity surface-emitting semiconductor laser 103.

The vertical-cavity surface-emitting semiconductor laser 103 includes a GaAs substrate 1, a first semiconductor stacked structure, a second semiconductor stacked structure, and a second DBR layer 12 in this order. The first semiconductor stacked structure is formed with a first DBR layer 2-3. The second semiconductor stacked structure includes a first conductivity-type semiconductor layer formed with an n-InP layer 3, a semiconductor active layer 4, and a second conductivity-type semiconductor layer formed with a p-InP layer 5, in this order from the side of the GaAs substrate 1.

The first semiconductor stacked structure includes 1-1st semiconductor layers 21 having a lattice constant greater than the lattice constant of the GaAs substrate 1, and 1-2nd semiconductor layers 22 having a lattice constant smaller than the lattice constant of the GaAs substrate 1. The 1-1st semiconductor layers 21 are formed with AlAs, and the 1-2nd semiconductor layers 22 are formed with GaAs_{0.097}P_{0.03}. Further, as described above, the second semiconductor stacked structure contains InP.

The first DBR layer 2-3 is formed with 1-1st semiconductor layers 21, 1-2nd semiconductor layers 22, and n-GaAs layers 23. Specifically, as illustrated in FIG. 3, in the first DBR layer 2-3, the side of the GaAs substrate 1 (the lower side in FIG. 3) is formed with a plurality of stacked structures (first pairs) of a 1-1st semiconductor layer 21 and a 1-2nd semiconductor layer 22, and the opposite side (the upper side in FIG. 3, the side of the n-InP layer 3) from the side of the GaAs substrate 1 is formed with a plurality of stacked structures (second pairs) of a 1-1st semiconductor layer 21 and an n-GaAs layer 23. For example, when the first DBR layer 2-3 is formed with 30 pairs, 15 pairs counted from the side of the GaAs substrate 1 may be formed with stacked structures (first pairs) of a 1-1st semiconductor layer 21 and a 1-2nd semiconductor layer 22, and the remaining 15 pairs may be formed with stacked structures (second pairs) of a 1-1st semiconductor layer 21 and an n-GaAs layer 23.

The contents described above regarding the vertical-cavity surface-emitting semiconductor laser according to the third embodiment (Example 3 of a vertical-cavity surface-emitting semiconductor laser) of the present technology can be applied to the vertical-cavity surface-emitting semiconductor laser and the method for manufacturing the vertical-cavity surface-emitting semiconductor laser according to the above-described first embodiment of the present technology, the vertical-cavity surface-emitting semiconductor laser according to the above-described second embodiment of the present technology, and the vertical-cavity surface-emitting semiconductor lasers according to the later-described fourth to sixth embodiments of the present technology, unless there is a specific technical contradiction.

### 5. Fourth Embodiment (Example 4 of a Vertical-Cavity Surface-Emitting Semiconductor Laser)

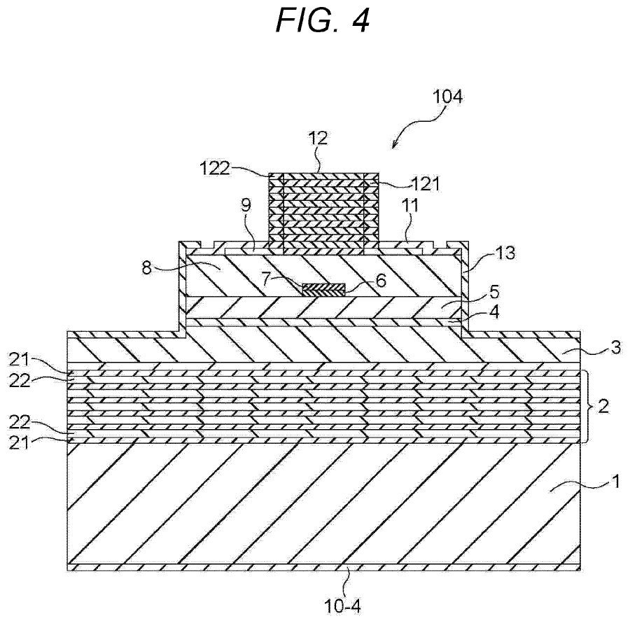

A vertical-cavity surface-emitting semiconductor laser according to a fourth embodiment (Example 4 of a vertical-cavity surface-emitting semiconductor laser) of the present technology is described with reference to FIG. 4.

FIG. 4 is a diagram illustrating an example configuration of a vertical-cavity surface-emitting semiconductor laser according to the fourth embodiment of the present technology, and specifically, is a cross-sectional diagram illustrating a vertical-cavity surface-emitting semiconductor laser 104.

The vertical-cavity surface-emitting semiconductor laser 104 includes a GaAs substrate 1, a first semiconductor stacked structure, a second semiconductor stacked structure, and a second DBR layer 12 in this order. The first semiconductor stacked structure is formed with a first DBR layer 2. The second semiconductor stacked structure includes a first conductivity-type semiconductor layer formed with an n-InP layer 3, a semiconductor active layer 4, and a second conductivity-type semiconductor layer formed with a p-InP layer 5, in this order from the side of the GaAs substrate 1.

The first DBR layer 2 forming the first semiconductor stacked structure includes 1-1st semiconductor layers 21 having a lattice constant greater than the lattice constant of the GaAs substrate 1, and 1-2nd semiconductor layers 22 having a lattice constant smaller than the lattice constant of the GaAs substrate 1. The 1-1st semiconductor layers 21 are formed with AlAs, and the 1-2nd semiconductor layers 22 are formed with GaAS_{0.097}P_{0.03}. Further, as described above, the second semiconductor stacked structure contains InP.

Note that, in the vertical-cavity surface-emitting semiconductor laser 104, the first DBR layer 2-2 and the 1-2nd semiconductor layer 22-2, or the first DBR layer 2-3 may be used in place of the first DBR layer 2 forming the vertical-cavity surface-emitting semiconductor laser 104.

Unlike the vertical-cavity surface-emitting semiconductor lasers 101 to 103 and 105 to 106, the vertical-cavity surface-emitting semiconductor laser 104 has a lower electrode 10-4 formed on the back surface of the GaAs substrate 1 (the surface on the opposite side of the GaAs substrate 1 from the surface (the front surface) on which the first DBR layer 2 is stacked). The first DBR layer 2 (an n-DBR layer; 1-1st semiconductor layers (n-AlAs layers) /1-2nd semiconductor layers (n-GaAS_{0.097}P_{0.03} layers) ) is doped with Si, and the doping concentration is about 5×10¹⁷ to 1×10¹⁸[cm⁻³].

The contents described above regarding the vertical-cavity surface-emitting semiconductor laser according to the fourth embodiment (Example 4 of a vertical-cavity surface-emitting semiconductor laser) of the present technology can be applied to the vertical-cavity surface-emitting semiconductor laser and the method for manufacturing the vertical-cavity surface-emitting semiconductor laser according to the above-described first embodiment of the present technology, the vertical-cavity surface-emitting semiconductor lasers according to the above-described second and third embodiments of the present technology, and the vertical-cavity surface-emitting semiconductor lasers according to the later-described fifth and sixth embodiments of the present technology, unless there is a specific technical contradiction.

### 6. Fifth Embodiment (Example 5 of a Vertical-Cavity Surface-Emitting Semiconductor Laser)

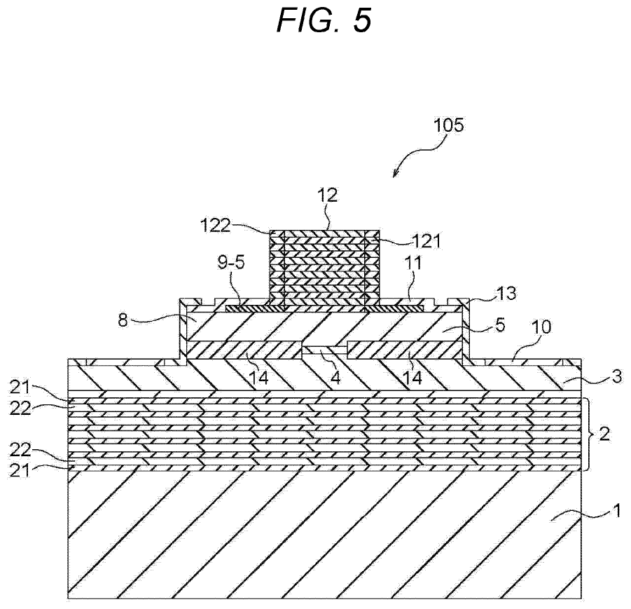

A vertical-cavity surface-emitting semiconductor laser according to a fifth embodiment (Example 5 of a vertical-cavity surface-emitting semiconductor laser) of the present technology is described with reference to FIG. 5.

FIG. 5 is a diagram illustrating an example configuration of a vertical-cavity surface-emitting semiconductor laser according to the fifth embodiment of the present technology, and specifically, is a cross-sectional diagram illustrating a vertical-cavity surface-emitting semiconductor laser 105.

The vertical-cavity surface-emitting semiconductor laser 105 includes a GaAs substrate 1, a first semiconductor stacked structure, a second semiconductor stacked structure, and a second DBR layer 12 in this order. The first semiconductor stacked structure is formed with a first DBR layer 2. The second semiconductor stacked structure includes a first conductivity-type semiconductor layer formed with an n-InP layer 3, a semiconductor active layer 4, and a second conductivity-type semiconductor layer formed with a p-InP layer 5, in this order from the side of the GaAs substrate 1.

The first DBR layer 2 forming the first semiconductor stacked structure includes 1-1st semiconductor layers 21 having a lattice constant greater than the lattice constant of the GaAs substrate 1, and 1-2nd semiconductor layers 22 having a lattice constant smaller than the lattice constant of the GaAs substrate 1. The 1-1st semiconductor layers 21 are formed with AlAs, and the 1-2nd semiconductor layers 22 are formed with GaAS_{0.097}P_{0.03}. Further, as described above, the second semiconductor stacked structure contains InP.

Note that, in the vertical-cavity surface-emitting semiconductor laser 105, the first DBR layer 2-2 and the 1-2nd semiconductor layer 22-2, or the first DBR layer 2-3 may be used in place of the first DBR layer 2 forming the vertical-cavity surface-emitting semiconductor laser 105.

### (Ion Implantation Narrowing)

The first DBR layer 2 (1-1st semiconductor layers (n-AlAs layers)/1-2nd semiconductor layers (n-GaAS_{0.097}P_{0.03} layers) ), and a GaAs buffer layer 25 are grown on the n-type GaAs substrate 1 by MOCVD. The thickness of each layer in the first DBR layer (n-DBR layer) 2 is 4/λ in optical thickness, and the number of pairs (stacked structures of a 1-1st semiconductor layer 21 and a 1-2nd semiconductor layer 22) is 30, for example.

Both layers are preferably undoped, but may be of the n-type with a doping concentration of about 5×10¹⁷ to 1×101⁸[cm⁻]. The dopant is Si, for example. An n-InP substrate 3 is bonded to the surface of the GaAs substrate 1 on the side of the first DBR layer 2 (the surface of the first DBR layer 2 on the opposite side from the side of the GaAs substrate 1). At this point of time, protons are implanted into the n-InP substrate 3 at a position of 100 nm from the surface, and the surface on the side into which the protons have been implanted is bonded to the GaAs substrate 1. As illustrated in FIG. 7C, the bonding is preferably direct bonding without interposition of metal or the like in between.

Next, the bonded n-InP substrate 3 is cut along the proton-implanted layer by heat treatment. As a result, the n-InP substrate 3 of 100 nm in thickness remains as a thin film on the side of the GaAs substrate 1. Next, the substrate (a semi-finished product) is placed in an MOCVD device, and the n-InP layer 3, an AlGaInAs/AlGaInAs multiple quantum well layer (the semiconductor active layer) 4, the p-InP layer 5, a tunnel junction layer of a p⁺-AlGaInAs layer 6/an n⁺-AlGaInAs layer 7, and an n-InP layer 8 are sequentially grown on the thin n-InP substrate 3.

Si can be used as an n-type dopant, and Mg can be used as a p-type dopant. The dopant in the p+-AlGaInAs layer 6 of the tunnel junction is preferably C, which is hardly diffused. Each doping concentration in the tunnel junction layer of the p⁺-AlGaInAs layer 6/the n⁺-AlGaInAs layer 7 may be 5×10¹⁹ [cm⁻³], and the doping concentrations in the other layers may be about 5×10¹⁷ to 1×10¹⁸ [cm⁻³].

In the AlGaInAs/AlGaInAs multiple quantum well layer (the semiconductor active layer) 4, the composition and the thickness may be designed so that the emission wavelength becomes 1450 nm, but it is preferable to apply opposite strains to the well layer and the barrier layer. The magnitude of the strains may be about 0.5%, and the number of wells may be four. The thicknesses of the p⁺-AlGaInAs layer 6 the n⁺-AlGaInAs layer 7 in the tunnel junction layer may be 20 nm/20 nm, and the tunnel junction layer of the p⁺-AlGaInAs layer 6/the n⁺-AlGaInAs layer 7 is preferably disposed at a position separated from the AlGaInAs/AlGaInAs multiple quantum well layer (the semiconductor active layer) 4 by an optical distance of λ/4.

The doping concentration in the n-InP layer 8 is 5 ×10¹⁷ to 1×10¹⁸ [cm⁻³], and the doping concentration in an n-InGaAs layer 9-5 is 2×10 ¹⁹[cm⁻³]. The wafer (a semi-finished product) is taken out from the MOCVD device, and protons (H⁺) are implanted into the wafer surface. At this point of time, a mask is formed with SiO₂ by a lithography process so that protons are not implanted into the region of 10 μm in inner diameter.

Conditions for implanting protons are set so that the conductivity of the proton-implanted region drops, and the resistance becomes higher in the proton-implanted region. In this manner, narrowing layers 14 by ion implantation are formed on both right and left sides of the AlGaInAs/AlGaInAs multiple quantum well layer (semiconductor active layer) 4.

After the mask is removed, and the n-InGaAs layer 9-5 as the uppermost layer is removed by selective etching to remain in a donut-like shape having an inner diameter of 10 μm and an outer diameter of 50 μm, a ring-like upper electrode 11 is formed over the remaining n-InGaAs layer 9-5. A mesa is formed by a lithography process so as to match the outer diameter of the upper electrode 11. At this point of time, a lower portion of the mesa is the n-InP layer 8, and the mesa is preferably formed by dry etching. After a lower electrode 10 is formed on the n-InP layer 3, the mesa side surfaces are insulated with a SiN layer 13 or the like. After that, a multilayer film of SiO₂ layers 121/Ta₂O₅ layers 122 is formed as the second DBR layer 12. Each thickness is λ/4 in optical thickness, and the number of pairs (stacked structures of a SiO₂ layer 121 and a Ta₂O₅ layer 122) is eight, for example. The portion of the multilayer film formed with the Si₂ layers 121/the Ta₂O₅ layers 122 formed outside the opening portion is selectively removed by a lithography process. Lastly, the device is singulated and mounted on a heat sink, and the electrodes are wire-bonded. In the above manner, the vertical-cavity surface-emitting semiconductor laser 105 is manufactured.

The contents described above regarding the vertical-cavity surface-emitting semiconductor laser according to the fifth embodiment (Example 5 of a vertical-cavity surface-emitting semiconductor laser) of the present technology can be applied to the vertical-cavity surface-emitting semiconductor laser and the method for manufacturing the vertical-cavity surface-emitting semiconductor laser according to the above-described first embodiment of the present technology, the vertical-cavity surface-emitting semiconductor laser according to the above-described second to fourth embodiments of the present technology, and the vertical-cavity surface-emitting semiconductor laser according to the later-described sixth embodiment of the present technology, unless there is a specific technical contradiction.

### 7. Sixth Embodiment (Example 6 of a Vertical-Cavity Surface-Emitting Semiconductor Laser)2

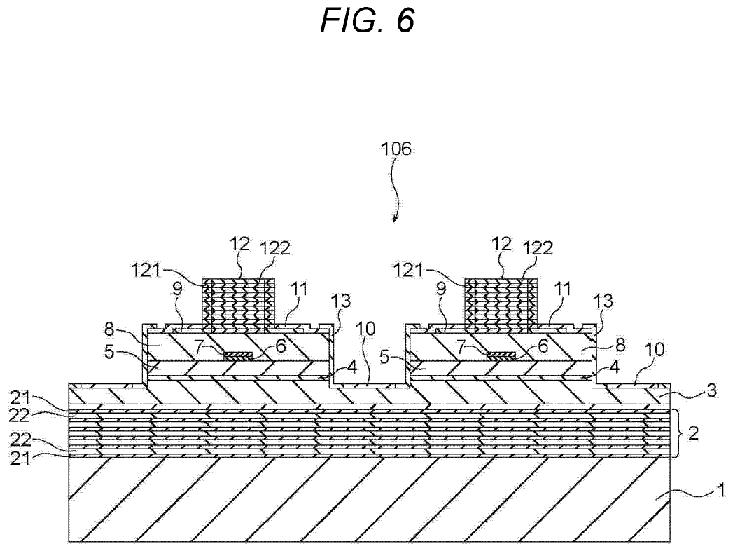

A vertical-cavity surface-emitting semiconductor laser according to a sixth embodiment (Example 6 of a vertical-cavity surface-emitting semiconductor laser) of the present technology is described with reference to FIG. 6.

FIG. 6 is a diagram illustrating an example configuration of a vertical-cavity surface-emitting semiconductor laser according to the sixth embodiment of the present technology, and specifically, is a cross-sectional diagram illustrating a vertical-cavity surface-emitting semiconductor laser 106.

The vertical-cavity surface-emitting semiconductor laser 106 includes a GaAs substrate 1, a first semiconductor stacked structure, a second semiconductor stacked structure, and a plurality (two in FIG. 6) of second DBR layers 12 in this order. The first semiconductor stacked structure is formed with a first DBR layer 2. The second semiconductor stacked structure includes a first conductivity-type semiconductor layer formed with an n-InP layer 3, a plurality (two in FIG. 6) of semiconductor active layers 4, and a second conductivity-type semiconductor layer formed with a plurality (two in FIG. 6) of p-InP layers 5, in this order from the side of the GaAs substrate 1.

In the vertical-cavity surface-emitting semiconductor laser 106, a plurality of semiconductor active layers 4, a plurality of p-InP layers 5, a plurality of tunnel junction layers of a p+-AlGaInAs layer 6/a n⁺-AlGaInAs layer 7, a plurality of n-InP layers 8, a plurality of n-InGaAs layers 9, a plurality of lower electrodes 10, a plurality of upper electrodes 11, and a plurality of second DBR layers 12 are formed, and the vertical-cavity surface-emitting semiconductor laser 106 is designed as a laser element in an array form (for example, each of the above components is formed with a 25 (5×5)-array). The pitch of the array is 50 μm, for example.

The first DBR layer 2 forming the first semiconductor stacked structure includes 1-1st semiconductor layers 21 having a lattice constant greater than the lattice constant of the GaAs substrate 1, and 1-2nd semiconductor layers 22 having a lattice constant smaller than the lattice constant of the GaAs substrate 1. The 1-1st semiconductor layers 21 are formed with AlAs, and the 1-2nd semiconductor layers 22 are formed with GaAs_{0.097}P_{0. 03}. Further, as described above, the second semiconductor stacked structure contains InP.

Note that, in the vertical-cavity surface-emitting semiconductor laser 106, the first DBR layer 2-2 and the 1-2nd semiconductor layer 22-2, or the first DBR layer 2-3 may be used in place of the first DBR layer 2 forming the vertical-cavity surface-emitting semiconductor laser 106.

The contents described above regarding the vertical-cavity surface-emitting semiconductor laser according to the sixth embodiment (Example 6 of a vertical-cavity surface-emitting semiconductor laser) of the present technology can be applied to the vertical-cavity surface-emitting semiconductor laser and the method for manufacturing the vertical-cavity surface-emitting semiconductor laser according to the above-described first embodiment of the present technology, and the vertical-cavity surface-emitting semiconductor lasers according to the above-described second to fifth embodiments of the present technology, unless there is a specific technical contradiction.

Note that embodiments of the present technology are not limited to the respective embodiments described above, but various modifications can be made to them without departing from the scope of the present technology.

Further, the effects described in the present specification are merely examples and are not restrictive, and there may be other effects.

Further, the present technology can also have the configurations described below.

[1]

A vertical-cavity surface-emitting semiconductor laser including:
a substrate;
a first semiconductor stacked structure including at least a first DBR layer;
a second semiconductor stacked structure in which at least a first conductivity-type semiconductor layer, a semiconductor active layer, and a second conductivity-type semiconductor layer are formed in order from a side of the substrate; and
a second DBR layer,
the substrate, the first semiconductor stacked structure, the second semiconductor stacked structure, and the second DBR layer being formed in order,
in which
the first semiconductor stacked structure includes at least a 1-1st semiconductor layer having a lattice constant greater than a lattice constant of the substrate, and a 1-2nd semiconductor layer having a lattice constant smaller than the lattice constant of the substrate, and
the second semiconductor stacked structure contains at least InP.
   [2]

The vertical-cavity surface-emitting semiconductor laser according to [1]or [2], in which the substrate includes a GaAs substrate.

[3]

The vertical-cavity surface-emitting semiconductor laser according to [1] or [2], in which
the first DBR layer includes the 1-1st semiconductor layer, and
the 1-1st semiconductor layer contains AlₓGa₁₋ₓAs (0<x≤1).
   [4]

The vertical-cavity surface-emitting semiconductor laser according to any one of [1] to [3], in which the 1-2nd semiconductor layer includes a mixed crystal semiconductor containing at least Ga and P.

[5]

The vertical-cavity surface-emitting semiconductor laser according to any one of [1] to [4], in which the 1-2nd semiconductor layer contains GaASₓP₁₋ₓ (0≤x 21 1) or GaₓIn₁₋ₓP (0≤x<1).

[6]

The vertical-cavity surface-emitting semiconductor laser according to any one of [1] to [5], in which the first DBR layer includes the semiconductor layer 1-2.

[7]

The vertical-cavity surface-emitting semiconductor laser according to any one of [1] to [6], in which
a thickness of the 1-2nd semiconductor layer is not greater than 5 μm, and
a rate of lattice mismatch of the 1-2nd semiconductor layer with the substrate is not higher than 1%
   [8]

The vertical-cavity surface-emitting semiconductor laser according to any one of [1] to [7], in which
the semiconductor active layer includes a quantum well structure formed with AlGaInAs or GaInAsP, and
an oscillation wavelength is not smaller than 1.2 μm and not greater than 2 μm.
   [9]

The vertical-cavity surface-emitting semiconductor laser according to any one of [1] to [8], in which the second DBR layer contains a dielectric material.

[10]

The vertical-cavity surface-emitting semiconductor laser according to [9], in which the dielectric material contains at least one compound selected from the group consisting of SiO₂, TiO₂, Ta₂O₃, SiN, amorphous Si, MgF₂, and CaF₂.

[11]

A method for manufacturing a vertical-cavity surface-emitting semiconductor laser, including at least:
growing a first semiconductor stacked structure on a substrate, the first semiconductor stacked structure including at least a first DBR layer;
bonding an InP substrate directly onto the first semiconductor stacked structure;
cutting off a portion of the InP substrate;
growing a second semiconductor stacked structure on the uncut InP substrate, the second semiconductor stacked structure including at least a first conductivity-type semiconductor layer, a semiconductor active layer, and a second conductivity-type semiconductor layer that are formed in order from a side of the substrate; and
forming a second DBR layer on the second semiconductor stacked structure.
   [12]

The method according to [11], in which the substrate includes a GaAs substrate.

[13]

The method according to [11] or [12], in which the first semiconductor stacked structure includes at least a 1-1st semiconductor layer having a lattice constant greater than a lattice constant of the substrate, and a 1-2nd semiconductor layer having a lattice constant smaller than the lattice constant of the substrate.

[14]

The method according to [13], in which
the first DBR layer includes the 1-1st semiconductor layer, and
the 1-1st semiconductor layer contains AlₓGa₁₋ₓAs (0<x<≤1).
   [15]

The method according to [13] or [14], in which the 1-2nd semiconductor layer includes a mixed crystal semiconductor containing at least Ga and P.

[16]

The method according to any one of [13] to [15], in which the 1-2nd semiconductor layer contains GaASₓP₁₋ₓ (0≤x>1) GaₓIn₁₋ₓP (0≤x<1).

[17]

The method according to any one of [13] to [16], in which the first DBR layer includes the 1-2nd semiconductor layer.

[18 ]

The method according to any one of [13] to [17], in which
a thickness of the 1-2nd semiconductor layer is not
greater than 5 μm, and
a lattice matching rate of the 1-2nd semiconductor layer with the substrate is not higher than 1%.
   [19 ]

The method according to any one of [11] to [18], in which
the semiconductor active layer includes a quantum well structure formed with AlGaInAs or GaInAsP, and
an oscillation wavelength is not smaller than 1.2 μm and not greater than 2 μm.
   [20]

The method according to any one of [11] to [19], in which the second DBR layer contains a dielectric material.

[21]

The method according to [20], in which the dielectric material contains at least one compound selected from the group consisting of SiO2, TiO₂, Ta₂O₅, SiN, amorphous Si, MgF₂, and CaF₂.

### REFERENCE SIGNS LIST

1 Substrate (GaAs substrate)
2 First DBR layer (first semiconductor stacked structure)
3 n-InP layer
4 Active layer
5 p-InP layer
6⁻-AlGaInAs layer
7 n⁺-AlGaInAs layer
8 n-InP layer
9 n-InGaAs layer
10, 10-4 Lower electrode
11 Upper electrode
12 Second DBR layer 13 SiN layer
21 1-1st semiconductor layer
22, 22-2 1-2nd semiconductor layer
101.102, 103, 104, 105, 106 Vertical-cavity surface-emitting semiconductor laser

1. A vertical-cavity surface-emitting semiconductor laser comprising:
substrate;
a first semiconductor stacked structure including at least a first DBR layer;
a second semiconductor stacked structure in which at least a first conductivity-type semiconductor layer, a semiconductor active layer, and a second conductivity-type semiconductor layer are formed in order from a side of the substrate; and
a second DBR layer,
the substrate, the first semiconductor stacked structure, the second semiconductor stacked structure, and the second DBR layer being formed in order,
wherein
the first semiconductor stacked structure includes at least a 1-1st semiconductor layer having a lattice constant greater than a lattice constant of the substrate, and a 1-2nd semiconductor layer having a lattice constant smaller than the lattice constant of the substrate, and
the second semiconductor stacked structure contains at least InP.

2. The vertical-cavity surface-emitting semiconductor laser according to claim 1, wherein the substrate includes a GaAs substrate.

3. The vertical-cavity surface-emitting semiconductor laser according to claim 1, wherein
the first DBR layer includes the 1-1st semiconductor layer, and
the 1-1st semiconductor layer contains AlₓGa₁₋ₓAs (0<x≤1).

4. The vertical-cavity surface-emitting semiconductor laser according to claim 1, wherein the 1-2nd semiconductor layer includes a mixed crystal semiconductor containing at least Ga and P.

5. The vertical-cavity surface-emitting semiconductor laser according to claim 1, wherein the 1-2nd semiconductor layer contains one of GaASₓP₁₋ₓ (0≤x<1) or GaₓIn₁₋ₓP (0≤x<1).

6. The vertical-cavity surface-emitting semiconductor laser according to claim 1, wherein the first DBR layer includes the semiconductor layer 1-2.

7. The vertical-cavity surface-emitting semiconductor laser according to claim 1, wherein
a thickness of the 1-2nd semiconductor layer is not greater than 5 μm, and
a rate of lattice mismatch of the 1-2nd semiconductor layer with the substrate is not higher than 1%.

8. The vertical-cavity surface-emitting semiconductor laser according to claim 1, wherein
the semiconductor active layer includes a quantum well structure formed with one of AlGaInAs or GaInAsp, and
an oscillation wavelength is not smaller than 1.2 um and not greater than 2 μm.

9. The vertical-cavity surface-emitting semiconductor laser according to claim 1, wherein the second DBR layer contains a dielectric material.

10. The vertical-cavity surface-emitting semiconductor laser according to claim 9, wherein the dielectric material contains at least one compound selected from the group consisting of SiO₂, TiO₂, Ta₂O₅, SiN, amorphous Si, MgF₂, and CaF₂.

11. A method for manufacturing a vertical-cavity surface-emitting semiconductor laser, comprising at least:
growing a first semiconductor stacked structure on a substrate, the first semiconductor stacked structure including at least a first DBR layer;
bonding an InP substrate directly onto the first semiconductor stacked structure;
cutting off a portion of the InP substrate;
growing a second semiconductor stacked structure on the uncut InP substrate, the second semiconductor stacked structure including at least a first conductivity-type semiconductor layer, a semiconductor active layer, and a second conductivity-type semiconductor layer that are formed in order from a side of the substrate; and
forming a second DBR layer on the second semiconductor stacked structure.

12. The method according to claim 11, wherein the substrate includes a GaAs substrate.

13. The method according to claim 11, wherein the first semiconductor stacked structure includes at least a 1-1st semiconductor layer having a lattice constant greater than a lattice constant of the substrate, and a 1-2nd semiconductor layer having a lattice constant smaller than the lattice constant of the substrate.

14. The method according to claim 13, wherein
the first DBR layer includes the 1-1st semiconductor layer, and
the 1-1st semiconductor layer contains AlₓGa₁₋ₓAs (0<x≤1).

15. The method according to claim 13, wherein the 1-2nd semiconductor layer includes a mixed crystal semiconductor containing at least Ga and P.

16. The method according to claim 13, wherein the 1-2nd semiconductor layer contains one of GaASₓP₁₋ₓ (0 ≤x <1) or GaxIn₁₋ₓP (0≤x<1).

17. The method according to claim 13, wherein the first DBR layer includes the 1-2nd semiconductor layer.

18. The method according to claim 13, wherein
a thickness of the 1-2nd semiconductor layer is not greater than 5 μm, and
a rate of lattice mismatch of the 1-2nd semiconductor layer with the substrate is not higher than 1%.

19. The method according to claim 11, wherein
the semiconductor active layer includes a quantum well structure formed with one of AlGaInAs or GaInAsP, and
an oscillation wavelength is not smaller than 1.2 um and not greater than 2 μm.

20. The method according to claim 11, wherein the second DBR layer contains a dielectric material.
